(19) United States
(12) Patent Application Publication
(10) Pub. No.: US 2005/0278132 A1
(43) Pub. Date: Dec. 15, 2005

(54) PWM dual store protection

(76) Inventor: Paul A. Bauerle, Fenton, MI (US)

Correspondence Address: General Motors Corporation;Legal Staff, Mail Code 482-C23-B21, 300 Renaissance Center, P.O. Box 300, Detroit, MI, 48265-3000, US

(21) Appl. No.: 11/052,461

(22) Filed: Feb. 7, 2005

Related U.S. Application Data
(60) Provisional application No. 60/578,238, filed on Jun. 9, 2004.

(51) Int. Cl. G01R 29/02; G01R 25/00; G06F 19/00

(52) U.S. Cl. 702/79

(57) ABSTRACT

A system for protectively storing a variable from a pulse-width modulated (PWM) signal comprises an input module that receives the PWM signal and measures times of rising and falling edges of the PWM signal. A memory module has storage for at least two variables. An arithmetic module performs subtraction and division. A control module communicates with the input module, the memory module, and the arithmetic module, and instructs the arithmetic module to calculate an on time, an off time, a period, a duty cycle, and a complementary percentage. The control module stores the duty cycle and the complementary percentage in the memory module.

### CROSS-REFERENCE TO RELATED APPLICATIONS

This application claims the benefit of U.S. Provisional Application No. 60/578,238, filed on Jun. 9, 2004. The disclosure of the above application is incorporated herein by reference.

### FIELD OF THE INVENTION

The present invention relates to protected storage of a PWM variable.

### BACKGROUND OF THE INVENTION

Referring now to FIG. 1, a graphical depiction of a pulse width modulated (PWM) signal 100 is shown. The PWM signal 100 has a constant period, denoted T_{period}. The time during which the signal is at a high voltage is referred to as the high time, or T_{high}, and the time when the signal is at a low voltage is the low time, denoted T_{low}. These numbers can be measured from a rising edge (transition of the signal from a low voltage to a high voltage) to rising edge 102 or from a falling edge (transition of the signal from a high voltage to a low voltage) to falling edge 104.

A sender communicates a value as a duty cycle of the PWM signal 100 to a receiver. Duty cycle is the ratio of time the signal is high to the period of the signal. Alternately, the signal of interest may be the off duty cycle, which is the ratio of time the signal is low to the period of the signal. By definition, duty cycle can vary between 0% and 100%, though values at the extremes are often not possible. At 0% or 100% duty cycle, there are no transitions for the receiver to synchronize with, or to measure the period of. Without a period measurement, the receiver can not ascertain whether the sender is stuck low or stuck high, or even off. Duty cycle is thus often restricted to a smaller range, such as 10% to 90%. The value that is to be transmitted via such a PWM signal must be scaled appropriately to fall between 10 and 90. Reverse scaling will then be performed by the receiver to recover the value.

### SUMMARY OF THE INVENTION

A system for protectively storing a variable from a pulse-width modulated (PWM) signal comprises an input module that receives the PWM signal and measures times of rising and falling edges of the PWM signal. A memory module has storage for at least two variables. An arithmetic module performs subtraction and division. A control module communicates with the input module, the memory module, and the arithmetic module, and instructs the arithmetic module to calculate an on time, an off time, a period, a duty cycle, and a complementary percentage. The control module stores the duty cycle and the complementary percentage in the memory module.

In other features, the on time is calculated as a time between a rising edge of the PWM signal and an immediately subsequent falling edge of the PWM signal, and the off time is calculated as a time between a falling edge of the PWM signal and an immediately subsequent rising edge of the PWM signal. The on time is calculated as a time between a falling edge of the PWM signal and an immediately subsequent rising edge of the PWM signal, and the off time is calculated as a time between a rising edge of the PWM signal and an immediately subsequent falling edge of the PWM signal.

In other features, the period is calculated as a time between a falling edge of the PWM signal and an immediately subsequent falling edge of the PWM signal. The period is calculated as a time between a rising edge of the PWM signal and an immediately subsequent rising edge of the PWM signal. The duty cycle is calculated as the on time divided by the period.

In other features, the complementary percentage is calculated by the arithmetic module to be a numeral one minus the off time divided by the period. The control module performs error handling when the period is outside of a range defined by a first limit and a second limit. The control module performs error handling when an absolute value of a difference between the duty cycle and the complementary percentage is greater than a resolution limit. The resolution limit is calibrated to be larger than a timing resolution of the input module and rounding errors of the arithmetic module.

Further areas of applicability of the present invention will become apparent from the detailed description provided hereinafter. It should be understood that the detailed description and specific examples, while indicating the preferred embodiment of the invention, are intended for purposes of illustration only and are not intended to limit the scope of the invention.

### BRIEF DESCRIPTION OF THE DRAWINGS

The present invention will become more fully understood from the detailed description and the accompanying drawings, wherein:

FIG. 1 is a graphical depiction of a pulse width modulated (PWM) signal;

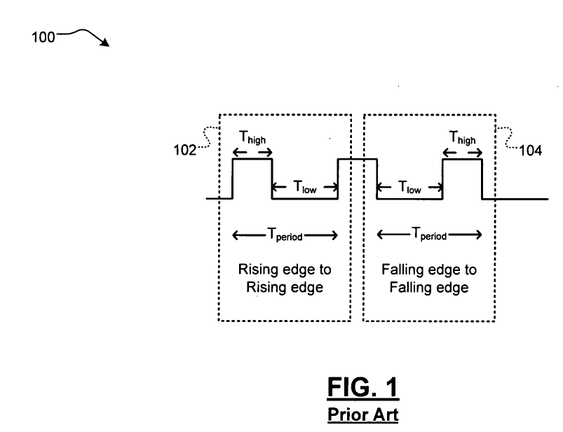

FIG. 2 is a block diagram depicting an exemplary implementation of a dual store pulse-width modulated (PWM) system; and

FIG. 3 is a flow chart of exemplary steps taken by the receiver of FIG. 2.

### DETAILED DESCRIPTION OF THE PREFERRED EMBODIMENTS

The following description of the preferred embodiments is merely exemplary in nature and is in no way intended to limit the invention, its application, or uses. For purposes of clarity, the same reference numbers will be used in the drawings to identify similar elements. As used herein, the term module refers to an application specific integrated circuit (ASIC), an electronic circuit, a processor (shared, dedicated, or group) and memory that execute one or more software or firmware programs, a combinational logic circuit, and/or other suitable components that provide the described functionality.

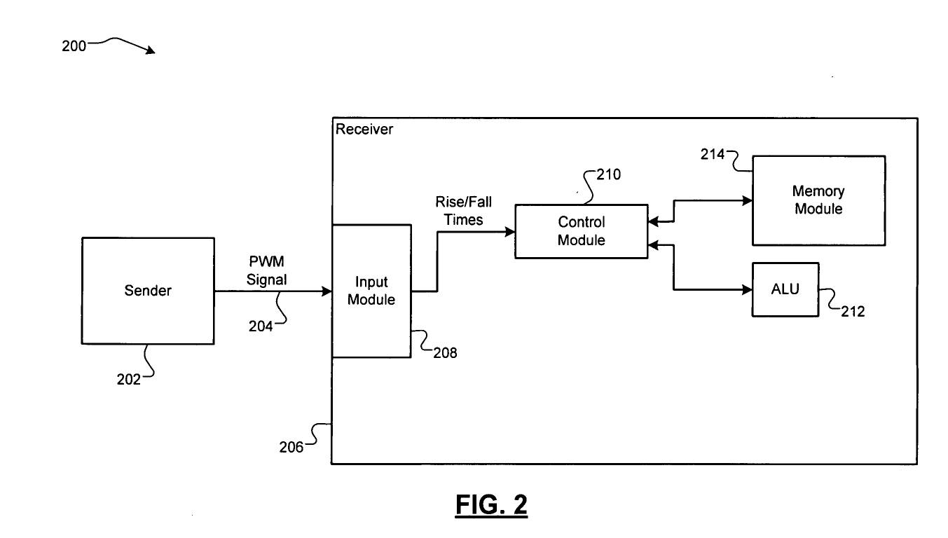

Referring now to FIG. 2, a block diagram depicting an exemplary implementation of a dual store pulse-width modulated (PWM) system 200 is depicted. A sender 202 communicates a value via a PWM signal 204 to a receiver 206. The sender 202 may have its own diagnostics to make sure that the value it sends is not corrupted. Within the receiver 206, an input module 208 receives the PWM signal 204. The input module 208 measures rise and/or fall times and communicates these times to a control module 210. The control module 210 communicates with an arithmetic logic unit (ALU) 212 and a memory module 214.

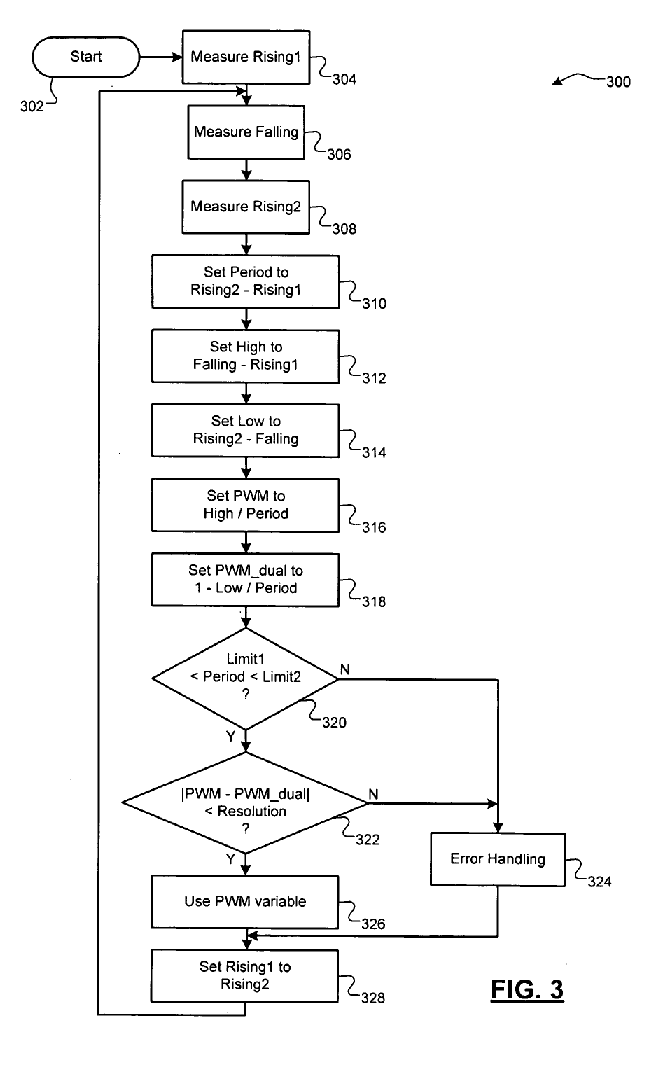

Referring now to FIG. 3, a flow chart 300 depicts exemplary steps taken by the receiver of FIG. 2. Control starts in step 302 and transfers to step 304. In step 304, the time of the first rising edge of the PWM signal is measured and stored into a variable, Rising1. Control transfers to step 306, where the time of a subsequent falling edge is measured and stored into a variable, Falling. Control transfers to step 308, where the time of a subsequent rising edge is measured and stored into a variable, Rising2. Control transfers to step 310, where the subtraction of Rising1 from Rising2 is stored into a variable, Period. Control transfers to step 312, where the subtraction of Rising1 from Falling is stored into a variable, High. Control transfers to step 314, where the subtraction of Falling from Rising2 is stored into a variable, Low.

Control transfers to step 316, where the division of high by period is stored into a variable, PWM. Control transfers to step 318, where one minus the quantity Low divided by Period is stored into a variable, PWM_dual. Control transfers to step 320, where Period is compared to two limits, Limit1 and Limit2. Limit1 and Limit2 may be capable of being calibrated, and may be stored in memory within the receiver, in external memory, or in registers. If Period is less than Limit2 and greater than Limit1, control transfers to step 322. Otherwise, if Period is greater than or equal to Limit2, or less than or equal to Limit1, control transfers to step 324. In step 322, if the absolute value of PWM minus PWM_dual is less than Resolution, control transfers to step 326. Otherwise, if the absolute value is greater than or equal to Resolution, control transfers to step 324. Resolution is also a calibratable value that may be stored within or outside of the receiver.

In step 324, error handling is performed because Period is outside the bounds set by Limit1 and Limit2, or the absolute difference between PWM and PWM_dual is greater than Resolution. A large difference between PWM and PWM_dual may signify a storage or arithmetic error because PWM and PWM_dual should be equal, excepting for the resolution of the input module and any mathematical rounding errors. These factors are accounted for in the value of Resolution. The period being outside of the set limits is an error condition, and may indicate that another line has capacitively coupled to the PWM signal, the sender is corrupted, or the input module is faulty. Error handling and/or correction must be performed. After performing applicable error handling in step 324, control transfers to step 328.

In step 326, the PWM variable is used in its typical capacity. For instance, the PWM variable could signify the amount of braking pressure requested by an anti-lock braking system (ABS) module, or the distance a throttle pedal has been depressed. Control then transfers to step 328, where the value of Rising2 is stored into the variable, Rising1. Control then returns to step 306, where this process is repeated. One skilled in the art will realize that the principles of the present invention would apply equally well if every reference to rising in FIG. 3 were replaced with falling and every reference to falling replaced with rising.

Those skilled in the art can now appreciate from the foregoing description that the broad teachings of the present invention can be implemented in a variety of forms. Therefore, while this invention has been described in connection with particular examples thereof, the true scope of the invention should not be so limited since other modifications will become apparent to the skilled practitioner upon a study of the drawings, the specification and the following claims.

1. A system for protectively storing a variable from a pulse-width modulated (PWM) signal, comprising:
an input module that receives the PWM signal and measures times of rising and falling edges of the PWM signal;
a memory module that has storage for at least two variables;
an arithmetic module that performs subtraction and division; and
a control module that communicates with said input module, said memory module, and said arithmetic module, and that instructs said arithmetic module to calculate an on time, an off time, a period, a duty cycle, and a complementary percentage,
wherein said control module stores said duty cycle and said complementary percentage in said memory module.

2. The system of claim 1 wherein said on time is calculated as a time between a rising edge of the PWM signal and an immediately subsequent falling edge of the PWM signal, and said off time is calculated as a time between a falling edge of the PWM signal and an immediately subsequent rising edge of the PWM signal.

3. The system of claim 1 wherein said on time is calculated as a time between a falling edge of the PWM signal and an immediately subsequent rising edge of the PWM signal, and said off time is calculated as a time between a rising edge of the PWM signal and an immediately subsequent falling edge of the PWM signal.

4. The system of claim 1 wherein said period is calculated as a time between a falling edge of the PWM signal and an immediately subsequent falling edge of the PWM signal.

5. The system of claim 1 wherein said period is calculated as a time between a rising edge of the PWM signal and an immediately subsequent rising edge of the PWM signal.

6. The system of claim 1 wherein said duty cycle is calculated as said on time divided by said period.

7. The system of claim 6 wherein said complementary percentage is calculated by said arithmetic module to be a numeral one minus said off time divided by said period.

8. The system of claim 1 wherein said control module performs error handling when said period is outside of a range defined by a first limit and a second limit.

9. The system of claim 1 wherein said control module performs error handling when an absolute value of a difference between said duty cycle and said complementary percentage is greater than a resolution limit.

10. The system of claim 9 wherein said resolution limit is calibrated to be larger than a timing resolution of said input module and rounding errors of said arithmetic module.

11. A method for protectively storing a variable from a pulse-width modulated (PWM) signal, comprising:
determining at least two of an on time, an off time, and a period time, of the PWM signal;
calculating a first parameter of interest from said at least two of an on time, an off time, and a period time;
calculating a second parameter of interest from said at least two of an on time, an off time, and a period time;
storing said first parameter and said second parameter; and
performing a comparison of said first parameter to said second parameter.

12. The method of claim 11 wherein determining said at least two of an on time, an off time, and a period time, includes measuring rise and fall times of the PWM signal.

13. The method of claim 11 wherein said comparison is true when said first parameter and said second parameter are within a tolerance of each other, and is false otherwise.

14. The method of claim 11 further comprising performing error handling if. said comparison is false, and using at least one of said first parameter and said second parameter if said comparison is true.

15. The method of claim 11 further comprising performing error handling if at least one of said period time and an addition of said on time and said off time is outside of a range defined by a first limit and a second limit.

16. A system for protectively storing a value from a pulse-width modulated (PWM) signal, comprising:
a receiving module that determines at least two of an on time, an off time, and a period time, based on rising and falling edges of the PWM signal;
a processing module that receives said times from said receiving module, and calculates a first value and a second value; and
a storage module that stores said first value and said second value, and retrieves at least one of said first value and said second value at a later time.

17. The system of claim 16 wherein said first value is calculated as said on time divided by said period time.

18. The system of claim 17 wherein said second value is calculated as one minus said off time divided by said period time.

19. The system of claim 16 wherein said processing module performs error handling when at least one of said period time and an addition of said on time and said off time is outside of a range defined by a first limit and a second limit.

20. The system of claim 16 wherein said processing module performs error handling when an absolute value of a difference between said first and said second value is greater than a resolution limit.
